(19) United States
(12) Patent Application Publication
(10) Pub. No.: US 2026/0082980 A1
(43) Pub. Date: Mar. 19, 2026

(54) SEMICONDUCTOR PACKAGE

(71) Applicant: Samsung Electronics Co., Ltd., Suwon-si (KR)

(72) Inventor: Duckgyu Kim, Suwon-si (KR)

(21) Appl. No.: 19/235,308

(22) Filed: Jun. 11, 2025

(30) Foreign Application Priority Data
Sep. 19, 2024 (KR) 10-2024-0126591

(51) Int. Cl. H10W 74/10; H10W 70/65; H10W 72/29; H10W 72/90

(52) U.S. Cl. CPC H10W 74/111; H10W 70/65; H10W 72/29; H10W 72/952

(57) ABSTRACT

A semiconductor package includes a semiconductor chip having chip pads on a horizontal first surface thereof; a redistribution wiring layer covering the first surface, and including redistribution wirings provided on at least one insulating layer and electrically connected to the chip pads, a protective layer on the at least one insulating layer covering the redistribution wirings and including a first cover portion having a first opening exposing a portion of a first redistribution wiring and a second cover portion covering second and third redistribution wirings adjacent to each other, and an under bump metallurgy (UBM) pad provided on the portion of the first redistribution wiring exposed by the first opening; and conductive bumps disposed on the UBM pads of the redistribution wiring layer. The first cover portion has a first vertical thickness, and the second cover portion may have a second vertical thickness less than the first thickness.

### PRIORITY STATEMENT

This application claims priority under 35 U.S.C. § 119 to Korean Patent Application No. 10-2024-0126591, filed on Sep. 19, 2024 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a wafer level package and a method of manufacturing the same.

### 2. Description of the Related Art

A semiconductor package such as wafer-level chip scale package (WLCSP) or fan-out wafer level package (FOWLP) may be mounted on a module board, an interposer, etc. via solder bumps formed on a redistribution wiring layer. In order to distribute stress when mounting the semiconductor package, a bonding pad structure such as an under bump metallurgy (UBM) pad may be applied under the solder bump to improve board level reliability (BLR). In addition, thicknesses of redistribution wirings may be increased in the redistribution wiring layer to improve power transmission characteristics. However, as the thickness of the redistribution wirings increases, a thickness of a passivation layer covering the redistribution wirings may also increase. Accordingly, a difference in shading between redistribution wirings adjacent to each other and lights reflected from the adjacent redistribution wirings may interfere with each other, thereby lowering the detection performance of the redistribution wirings. Further, stress between the passivation layer and the UBM pad may increase due to an increase in the thickness of a via portion of the UBM pad formed on the passivation layer, causing a crack to occur in the UBM pad.

### SUMMARY

Example embodiments provide a semiconductor package having a structure capable of improving detection performance in a visual inspection process and improving adhesion between an UBM pad and a passivation layer.

Example embodiments provide a method of manufacturing the semiconductor package.

According to example embodiments, a semiconductor package includes a semiconductor chip having chip pads on a first surface thereof, wherein the first surface is a horizontal surface; a redistribution wiring layer covering the first surface of the semiconductor chip, the redistribution wiring layer including redistribution wirings provided on at least one insulating layer and electrically connected to the chip pads, a protective layer on the at least one insulating layer wherein the protective layer covers the redistribution wirings and includes a first cover portion having a first opening that exposes a portion of a first redistribution wiring of the redistribution wirings with respect to the first cover portion and a second cover portion covering second and third redistribution wirings adjacent to each other of the redistribution wirings, and an under bump metallurgy (UBM) pad provided on the portion of the first redistribution wiring exposed by the first opening, and wherein the protective layer including the first and second cover portions is a continuous integral structure; and conductive bumps disposed on the UBM pads of the redistribution wiring layer. The first cover portion has a first thickness in a vertical direction, and the second cover portion has a second thickness in the vertical direction less than the first thickness.

According to example embodiments, a semiconductor package includes a semiconductor chip having chip pads on a first surface thereof, wherein the first surface is a horizontal surface; a redistribution wiring layer covering the first surface of the semiconductor chip and having redistribution wirings electrically connected to the chip pads; and conductive bumps disposed on an outer surface of the redistribution wiring layer and electrically connected to the redistribution wirings. The redistribution wiring layer includes the redistribution wirings provided on at least one insulating layer; a protective layer provided on the at least one insulating layer and covering the redistribution wirings, the protective layer including a first cover portion having a first opening that exposes a portion of a first redistribution wiring of the redistribution wirings with respect to the first cover portion, and a second cover portion covering second and third redistribution wirings adjacent to each other of the redistribution wirings, wherein the protective layer including the first and second cover portions is a continuous integral structure; and a bonding pad provided on the portion of the first redistribution wiring. The conductive bumps are disposed on the bonding pads respectively. The first cover portion has a first thickness in a vertical direction, and the second cover portion has a second thickness in the vertical direction less than the first thickness.

According to example embodiments, a semiconductor package includes a redistribution wiring layer having at least one insulating layer and redistribution wirings provided on the at least one insulating layer; a semiconductor chip arranged on an upper surface of the redistribution wiring layer and having chip pads that are electrically connected to the redistribution wirings, wherein the upper surface is horizontal; and external connection terminals disposed on a lower surface of the redistribution wiring layer and electrically connected to the redistribution wirings. The redistribution wiring layer further includes a protective layer provided on the at least one insulating layer and covering the redistribution wirings, the protective layer including a first cover portion having a first opening that exposes a portion of a first redistribution wiring of the redistribution wirings with respect to the first cover portion, and a second cover portion covering second and third redistribution wirings adjacent to each other of the redistribution wirings, wherein a topmost surface of the first cover portion and a topmost surface of the second cover portion are on the same horizontal plane, and a bottom surface of the first cover portion and a bottom surface of the second cover portion are on different horizontal planes such that the bottom surface of the first cover portion is lower than the bottom surface of the second cover portion, and the first cover portion and second cover portion have the same material composition from their respective topmost surfaces to their respective bottom surfaces; and a bonding pad provided on the portion of the first redistribution wiring. An external connection terminal of the external connection terminals is disposed on the bonding pads. The first cover portion has a first thickness in a vertical direction, and the second cover portion has a second thickness in the vertical direction less than the first thickness.

According to example embodiments, a semiconductor package may include a semiconductor chip having chip pads, a redistribution wiring layer on a surface of the semiconductor chip and having redistribution wirings that are electrically connected to the chip pads, and conductive bumps disposed on an outer surface of the redistribution wiring layer and electrically connected to the redistribution wirings.

The redistribution wiring layer may include a protective layer having a first cover portion with a first opening that exposes a portion of a first redistribution wiring among the redistribution wirings and a second cover portion covering second and third redistribution wirings among the redistribution wirings that are adjacent to each other, and an UBM pad disposed on the portion of the first redistribution wiring. A step portion may be provided in a sidewall of the first opening.

A vertical thickness of a remaining portion of the protective layer excluding the second cover portion may be greater than a vertical thickness of the second cover portion. Accordingly, the redistribution wiring may be formed to have a relatively large thickness, to thereby improve power transmission characteristics. In addition, since the second cover portion of the protective layer has the relatively thin thickness, detection reliability in a visual inspection process after a packaging process may be improved. Further, the step portion formed within the first opening may increase a bonding area between the UBM pad to provide excellent interfacial adhesion between the UBM pad and the sidewall of the first opening of the protective layer.

According to example embodiments, a method of manufacturing a semiconductor package comprises providing a semiconductor wafer including a substrate, and in which a plurality of semiconductor chips are formed; forming a redistribution wiring layer on a surface of the substrate, wherein: the redistribution wiring layer includes redistribution wirings provided on at least one insulating layer, a protective layer on the at least one insulating layer, and an under bump metallurgy (UBM) pad; the protective layer covers the redistribution wirings and includes a first cover portion having a first opening that exposes a portion of a first redistribution wiring of the redistribution wirings with respect to the first cover portion and a second cover portion covering second and third redistribution wirings adjacent to each other of the redistribution wirings; forming the redistribution wiring layer comprises: performing a first etching process to form the first opening in the first cover portion; and performing a second etching process to form a second opening in the second cover portion and form a step portion in a sidewall of the first opening together; and the first cover portion has a first thickness in a vertical direction, and the second cover portion has a second thickness in the vertical direction less than the first thickness; and forming external connection terminals on the redistribution wiring layer to be electrically connected to the redistribution wirings.

In example embodiments, the first and second etching processes may use photoresist patterns as etching masks.

In example embodiments, forming the redistribution wiring layer on the surface of the substrate may further include: forming a first insulating layer having openings that expose chip pads on the surface of the substrate; forming the redistribution wirings on the first insulating layer; forming a first seed layer on the first insulating layer and the chip pads in the openings of the first insulating layer; forming a first photoresist pattern having openings that expose redistribution wiring regions on the first seed layer; performing an electrolytic plating process to form the redistribution wirings in the openings of the first photoresist pattern; forming the protective layer on the first insulating layer to cover the redistribution wirings; forming a second photoresist pattern; forming a third photoresist pattern; forming a second seed layer on the protective layer; forming a fourth photoresist pattern; and performing an electrolytic plating process to form the UBM pad as a bonding pad.

In example embodiments, forming the redistribution wirings on the first insulating layer may include forming the redistribution wirings to be electrically connected to the chip pads through the openings of the first insulating layer; forming the second photoresist pattern comprises forming the second photoresist pattern having an opening that exposes a region corresponding to a portion of the first redistribution wiring on the protective layer; forming the third photoresist pattern comprises forming the third photoresist pattern having an opening that exposes a second cover portion region and an opening that exposes a region corresponding to a portion of a sidewall on the protective layer; forming the fourth photoresist pattern comprises forming the fourth photoresist pattern having an opening that exposes an UBM pad region on the second seed layer; and performing the electrolytic plating process comprises performing the electrolytic plating process to form the UBM pad as a bonding pad within the opening of the fourth photoresist pattern.

### BRIEF DESCRIPTION OF THE DRAWINGS

Example embodiments will be more clearly understood from the following detailed description taken in conjunction with the accompanying drawings. FIGS. 1 to 23 represent non-limiting, example embodiments as described herein.

FIG. 1 is a cross-sectional view illustrating a semiconductor package in accordance with example embodiments.

FIG. 2 is a plan view illustrating the semiconductor package in FIG. 1.

FIG. 3 is an enlarged cross-sectional view illustrating portion ‘A’ in FIG. 1.

FIG. 4 is a plan view illustrating a passivation layer in FIG. 3.

FIGS. 5 to 21 are views illustrating a method of manufacturing a semiconductor package in accordance with example embodiments.

FIG. 22 is a cross-sectional view illustrating a semiconductor package in accordance with example embodiments.

FIG. 23 is an enlarged cross-sectional view illustrating portion ‘F’ in FIG. 22.

### DETAILED DESCRIPTION OF EXAMPLE EMBODIMENTS

Hereinafter, example embodiments will be explained in detail with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially”may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second”in the specification or another claim).

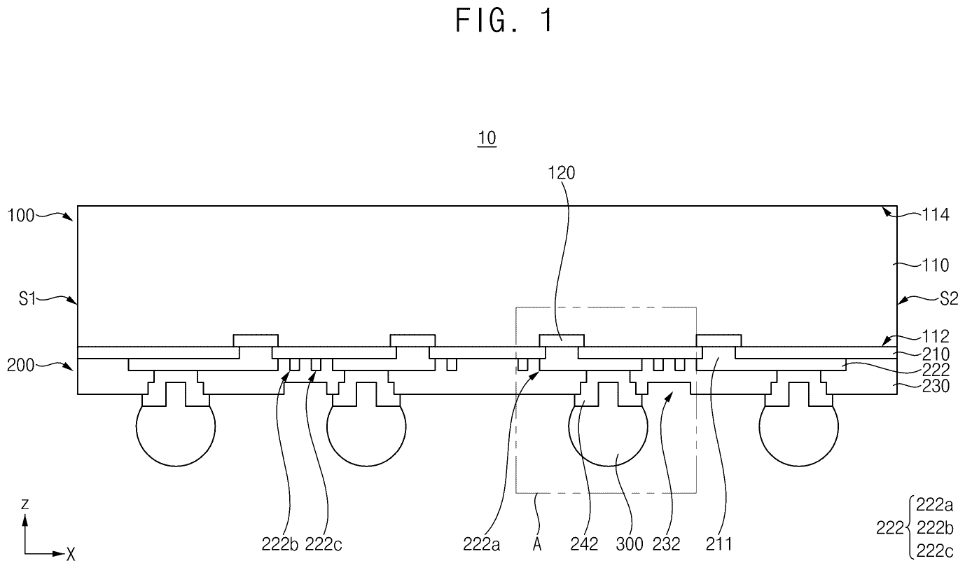

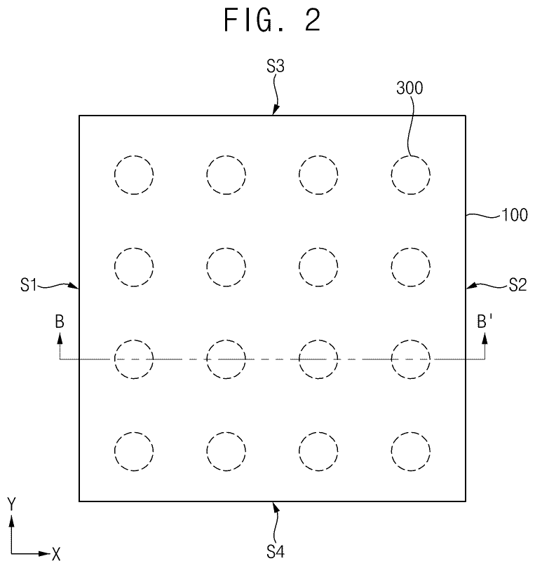

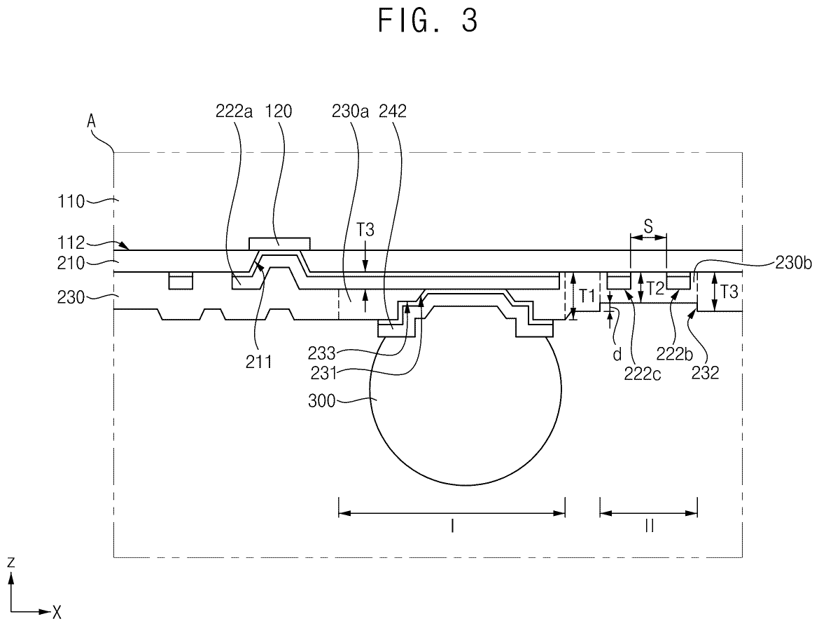

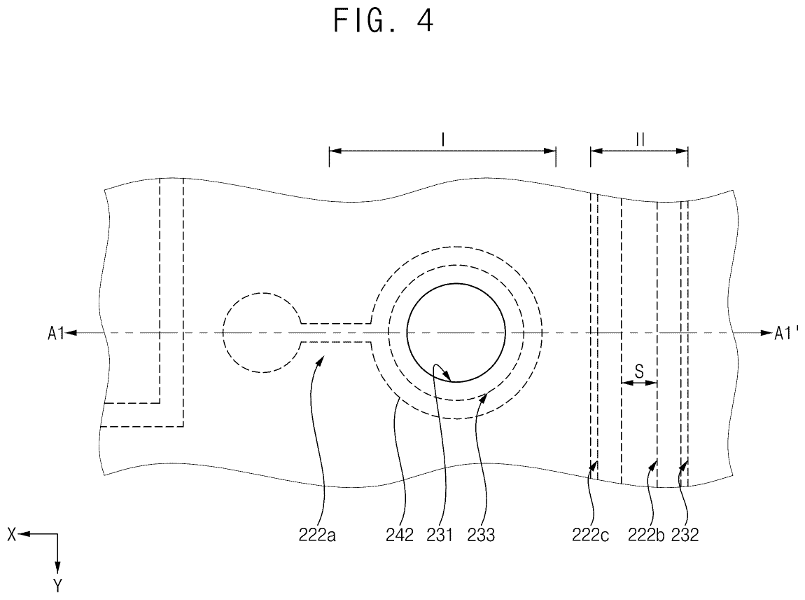

FIG. 1 is a cross-sectional view illustrating a semiconductor package in accordance with example embodiments. FIG. 2 is a plan view illustrating the semiconductor package in FIG. 1. FIG. 3 is an enlarged cross-sectional view illustrating portion ‘A’ in FIG. 1. FIG. 4 is a plan view illustrating a passivation layer with an under bump metallurgy (UBM) pad in FIG. 3. Note that the cross-sectional view of FIG. 1 is taken along the line B-B′ in FIG. 2. Likewise, the cross-sectional view of FIG. 3 may be taken along the line A1-A1′ in FIG. 4, which may be a segment (e.g., portion) of the line B-B′ in FIG. 2. The conductive bump 300 is omitted from FIG. 4 on the illustrated UBM pad 242, but is shown in FIG. 3.

Referring to FIGS. 1 to 4, a semiconductor package 10 may include a semiconductor chip 100, a redistribution wiring layer 200 disposed on one surface of the semiconductor chip 100 and external connection members (e.g., external connection terminals such as conductive bumps) 300 disposed on an outer surface of the redistribution wiring layer 200.

In example embodiments, the semiconductor package 10 may be a wafer level chip scale package (WLCSP). The semiconductor chip 100 of the semiconductor package 10 may include a Power Management Integrated Circuit (PMIC). The semiconductor chip 100 may include an integrated circuit for performing functions related to a power source, such as a power management semiconductor, battery management, a DC-DC converter, etc.

In example embodiments, the semiconductor chip 100 may include a substrate 110 having a first surface 112 and a second surface 114 opposite to the first surface 112. Circuit elements (not shown) may be formed on the first surface 112 of the substrate 110. The circuit elements may include, for example, transistors, capacitors, wiring structures, etc. An insulation interlayer (not shown) may be formed on the first surface 112 of the substrate 110 to cover the circuit elements.

A plurality of chip pads 120 may be formed on the first surface 112 of the substrate 110. The chip pads 120 may be electrically connected to the circuit elements through contact plugs in the insulation interlayer (not shown). A passivation layer may be formed on the insulation interlayer (not shown) on the first surface 112 of the substrate 110. At least portions of the chip pads 120 may be exposed by the passivation layer.

Although only some chip pads are illustrated in the figures, structures and arrangements of the chip pads are provided as examples, and it will be understood that the present disclosure is not limited thereto.

As illustrated in FIG. 2, the semiconductor chip 100 may have a first side surface S1 and a second side surface S2 extending in a direction parallel with a first direction (Y direction) perpendicular to the first surface and opposite to each other, and a third side surface S3 and a fourth side surface S4 extending in a direction parallel with a second direction (X direction) perpendicular to the first direction and opposite to each other. The X and Y directions may also be referred to herein as horizontal directions, while a third direction (Z direction) perpendicular to both may be referred to as a vertical direction.

In example embodiments, the redistribution wiring layer 200 may be provided on the first surface 112 of the substrate 110. The redistribution wiring layer 200 may include at least one insulating layer 210 (e.g., a first insulating layer 210) and redistribution wirings 222 (e.g., uppermost redistribution wirings 222) provided on the at least one insulating layer and electrically connected to the chip pads 120.

In particular, a first insulating layer 210 may be provided on the first surface 112 of the substrate 110. The first insulating layer 210 may have openings 211 that expose the chip pads 120 respectively (e.g., with respect to the first insulating layer 210). The first insulating layer may include a polymer or a dielectric layer. For example, the first insulating layer may include a photosensitive dielectric layer such as PID (photo imageable dielectric).

The redistribution wirings 222 may be provided on the first insulating layer 210 and may be electrically connected to the chip pads 120 through the openings 211. The redistribution wiring may include aluminum (Al), copper (Cu), tin (Sn), nickel (Ni), gold (Au), platinum (Pt), or an alloy thereof. The redistribution wiring may be formed by a plating process, an electroless plating process, a vapor deposition process, etc.

In particular, the redistribution wirings 222 may include a first redistribution wiring 222a on which an under bump metallurgy (UBM) pad 242 is disposed, and second and third redistribution wirings 222b, 222c adjacent to each other. A spacing distance S between the second and third redistribution wirings 222b, 222c may be within a range of 3 μm to 30 μm. The redistribution wiring layer 200 may include a first region I on which the UBM pad 242 is disposed, and a second region II on which the second and third redistribution wirings 222b, 222c adjacent to each other are disposed.

In the second region II, two adjacent second and third redistribution wirings 222b, 222d may be disposed, but the present disclosure may not be limited thereto, and, for example, three or more redistribution wirings adjacent to each other may extend in the second region II. In addition, the adjacent redistribution wirings within the second region II may extend in one direction (Y direction). For example, the first wiring 222a may extend lengthwise in a first horizontal direction (e.g., X direction), and each of the second and third wirings 222b and 222c may extend lengthwise in a second horizontal direction (e.g., Y direction) different from the first horizontal direction (e.g., perpendicular to the first horizontal direction).

The first redistribution wiring 222a may be electrically connected to the chip pad 120 through the opening 211 of the first insulating layer 210. The first redistribution wiring 222a may include a redistribution via disposed within the opening 211 of the first insulating layer 210, a redistribution line extending from the redistribution via on the first insulating layer 210, and a redistribution pad in one end portion of the redistribution line. The UBM pad 242 may be disposed on the redistribution pad, which is a portion of the first redistribution wiring 222a.

In example embodiments, the redistribution wiring layer 200 may include a protective layer 230 as a passivation layer provided on the first insulating layer 210 and may include the UBM pad 242 as a bonding pad provided on the portion of the first redistribution wiring 222a exposed by the protective layer 230.

In particular, the protective layer 230 may be provided on the first insulating layer 210 to cover the redistribution wirings 222. The protective layer 230 may include a polymer or a dielectric layer. For example, the protective layer may include an oxide layer, a nitride layer, or a combination thereof. The protective layer may include a thermosetting resin such as epoxy mold compound (EMC), or an insulating material such as polyimide. The protective layer may include a photosensitive dielectric layer such as photo imageable dielectric (PID) or a non-photosensitive dielectric layer. The protective layer may be formed by a vapor deposition process, a spin coating process, a molding process, a lamination process, a coating process, etc.

As illustrated in FIGS. 3 and 4, the protective layer 230 may include a first cover portion 230a provided in the first region I and a second cover portion 230b provided in the second region II. The first cover portion 230a may cover a portion of the first redistribution wiring 222a on which the UBM pad 242 is disposed. The second cover portion 230b may cover the second and third redistribution wirings 222b, 222c that are adjacent to each other. In some examples, the first cover portion 230a and second cover portion 230b may be part of the protective layer 230. For example, the protective layer 230 including the first and second cover portions 230a and 230b is a continuous integral structure. In another example, the first and second cover portions 230a and 230b may contain the same material or materials as the protective layer 230. In yet another example, respective topmost surfaces of the first and second cover portions 230a and 230b may be on the same horizontal plane, and respective bottom surfaces of first and second cover portions 230a and 230b may be on different horizontal planes, such that the bottom surface of the first cover portion 230a is lower than the bottom surface of the second cover portion 230b. In this example, the first and second cover portions 230a and 230b may have the same material composition from their respective topmost surfaces to their respective bottom surfaces.

The first cover portion 230a may have a first opening 231 that exposes a portion of the first redistribution wiring 222a. A sidewall of the first opening 231 may be inclined by a predetermined angle with respect to an upper surface of the first cover portion. A diameter of the first opening 231 may be determined in consideration of a diameter of the UBM pad. The second cover portion 230b may include a second opening 232 having a predetermined depth d (not labeled) from the upper surface of the protective layer 230. The first cover portion 230a may have a first vertical thickness T1 (e.g., in the Z direction), and the second cover portion 230b may have a second vertical thickness T2 less than the first thickness T1.

A step portion 233 may be provided in the sidewall of the first opening 231. The step portion 233 may have an annular shape when viewed in a plan view, as in FIG. 4. A width of the annular shape of the step portion 233 may be within a range of 2.5% to 5% of the diameter of the first opening 231 (not shown to scale).

The UBM pad 242 may be formed on a portion of the first redistribution wiring 222a. The UBM pad 242 may have a via portion provided within the first opening 231. The UBM pad 242 may include a single plating pattern layer such as copper. Alternatively, the UBM pad 242 may include the plating pattern layer and an additional plating pattern layer formed on the plating pattern layer. The additional plating pattern layer may include a metal such as nickel or gold. For example, a diameter of the UBM pad 242 may be within a range of 100 μm to 250 μm.

In this embodiment, the redistribution wiring layer may be formed to include the first insulating layer and the protective layer (second insulating layer) formed in two layers, and the redistribution wirings provided in the first and second insulating layers. However, the present disclosure may not be limited thereto, and for example, the redistribution wiring layer may include first and second insulating layers and a protective layer (third insulating layer) stacked in at least three layers, and first and second redistribution wirings respectively provided in the first, second, and third insulating layers. In this case, the second redistribution wiring may correspond to an uppermost redistribution wiring among the redistribution wirings, and the UBM pad may be formed on a protruding portion of the uppermost redistribution wiring (second redistribution wiring) exposed by the protective layer.

In example embodiments, the conductive bumps 300 as external connection members may be respectively disposed on the UBM pads 242 of the redistribution wiring layer 200. For example, the conductive bumps 300 may include solder bumps or solder balls.

The conductive bump 300 may contact a portion of the redistribution wiring 222 exposed by the UBM pad 242. The conductive bump 300 may be provided on the portion of the first redistribution wiring 222a exposed by the UBM pad 242.

As described above, the semiconductor package 10 may include the semiconductor chip 100 having the chip pads 120 on the first surface 112 thereof, the redistribution wiring layer 200 covering the first surface 112 of the semiconductor chip 100 and having the redistribution wirings 222 that are electrically connected to the chip pads 120, and the conductive bumps 300 disposed on the outer surface of the redistribution wiring layer 200 and electrically connected to the redistribution wirings 222.

The redistribution wiring layer 200 may include the redistribution wirings 222 provided on the at least one insulating layer 210, the protective layer 230 having the first cover portion 230a with the first opening 231 that exposes a portion of the first redistribution wiring 222a and the second cover portion 230b covering the second and third redistribution wirings 222b, 222c among the redistribution wirings that are adjacent to each other, and the UBM pad 242 disposed on the portion of the first redistribution wiring 222a exposed by the first opening 231. The conductive bump 300 may be disposed on the UBM pad 242. The step portion 233 may be provided in the sidewall of the first opening 231.

A vertical thickness of a remaining portion of the protective layer 230 excluding the second cover portion 230b may be greater than the second vertical thickness T2 of the second cover portion 230b. Since the remaining portion of the protective layer 230 includes the first cover portion 230a and has a relatively large thickness, the redistribution wiring 222 may be formed to have a relatively large vertical thickness T3, to thereby improve power transmission characteristics.

In addition, since the second cover portion 230b of the protective layer 230 has the relatively thin vertical thickness T2, in a visual inspection process after forming the conductive bump 300 on the protective layer 230 in a wafer level packaging process, refraction of light reflected from the adjacent second and third redistribution wirings 222b, 222c and a difference in shading above the second and third redistribution wirings 222b, 222c may be reduced, thereby improving detection reliability. For example, the visual inspection process may be an automated visual inspection (AVI) process, for example a final vision inspection on the redistribution wiring layer of the final package. In case the protective layer covering the redistribution wirings has a relatively greater thickness, light reflected off the adjacent second and third redistribution wirings 222b, 222c and passing through the protective layer 230 may result in interference, thereby reducing the detection performance between the second and third redistribution wirings 222b, 222c. For example, since the protective layer covering the adjacent second and third redistribution wirings has tapered sidewalls at an upper portion between the adjacent second and third redistribution wirings due to the thick thickness, light reflected off each of the adjacent second and third redistribution wirings may be refracted and result in interference when passing through the tapered sidewalls of the protective layer. However, according to example embodiments, the second cover portion 230b including the second opening 232 may have the relatively thin vertical thickness to reduce the refraction of light reflected off the adjacent second and third redistribution wirings 222b, 222c and passing through the protective layer 230, thereby improving the detection performance between the second and third redistribution wirings 222b, 222c in the AVI process. Since the protective layer 230 has the second opening 232 at the upper portion between the adjacent second and third redistribution wirings 222b, 222c, the upper portion of the protective layer 230 covering the adjacent second and third redistribution wirings may have a flat surface between the second and third redistribution wirings. Accordingly, light reflected off the second and third redistribution wirings may not be refracted when passing through the flat surface of the protective layer, thereby preventing the different reflected light from interference.

For example, the thickness T3 may be the maximum vertical thickness of the first cover portion 230a, and the thickness T2 may be the maximum vertical thickness of the second cover portion 230b. The first cover portion 230a may cover a first region (e.g., region I) on a first side of the UBM pad 242, and the second cover portion 230b may cover a second region (e.g., region II) on a second side of the UBM pad 242 opposite the first side. Alternatively or additionally, as in the example of FIG. 3, the UBM pad 242 may be disposed on part of region I, while first cover portion 230a and second cover portion 230b may be located on opposite sides of UBM pad 242.

Further, the step portion 233 formed within the first opening 231 may increase a bonding area between the UBM pad 242 to provide excellent interfacial adhesion between the UBM pad 242 and the sidewall of the first opening 231 of the protective layer 230. Accordingly, reliability (e.g., in a board level test) may be improved.

Hereinafter, a method of manufacturing the semiconductor package of FIG. 1 will be described.

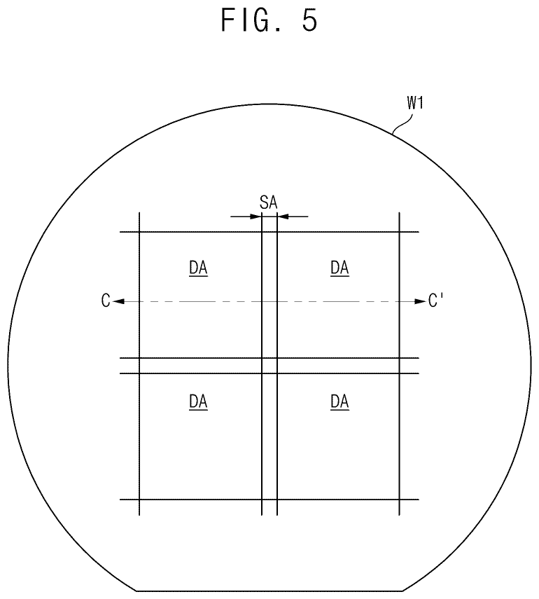

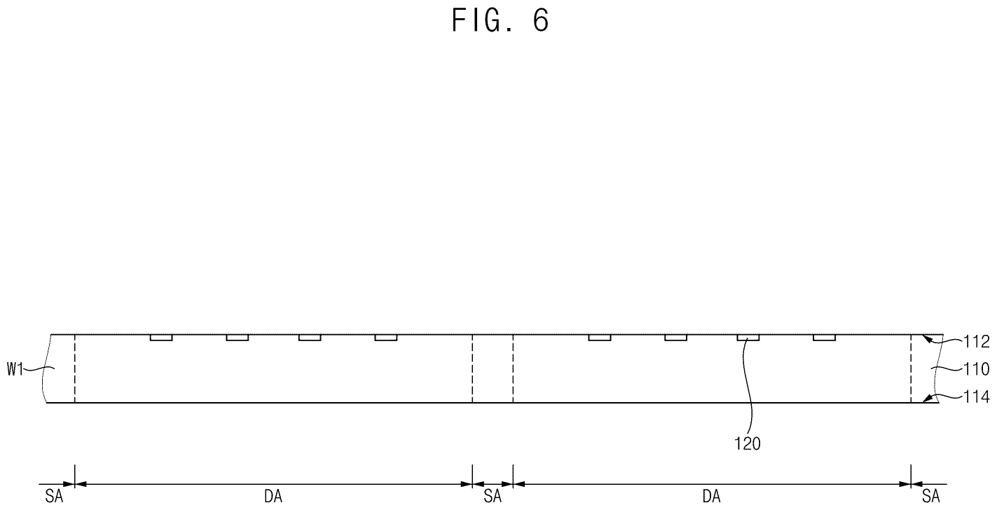

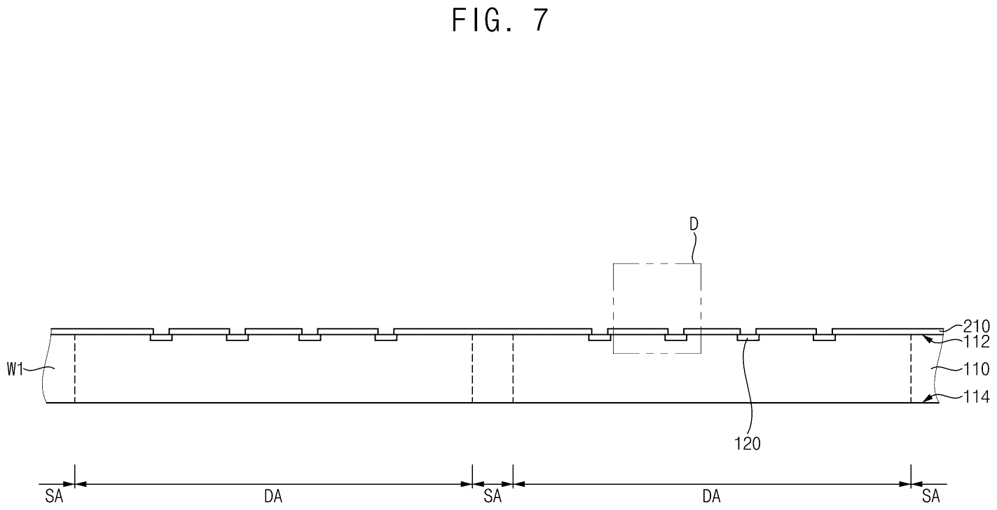

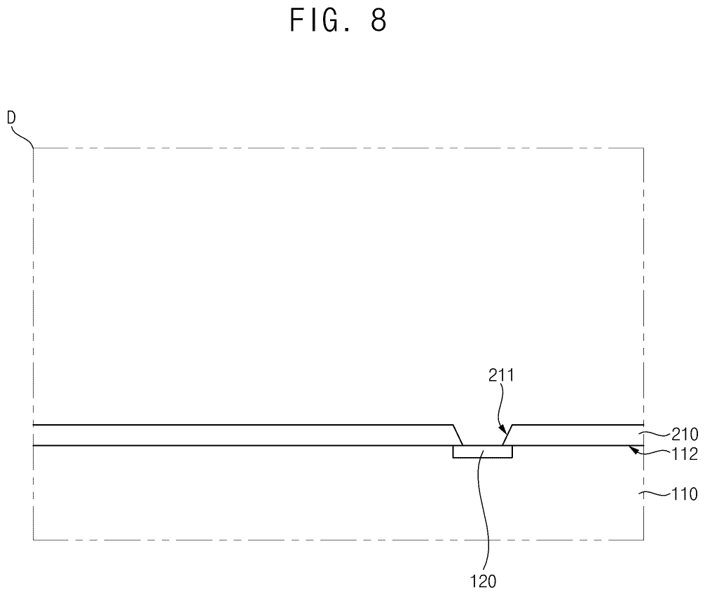

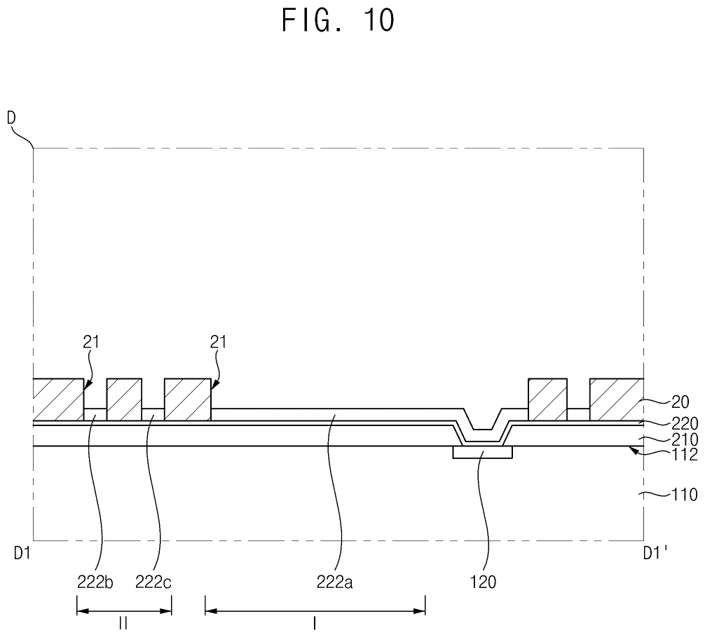

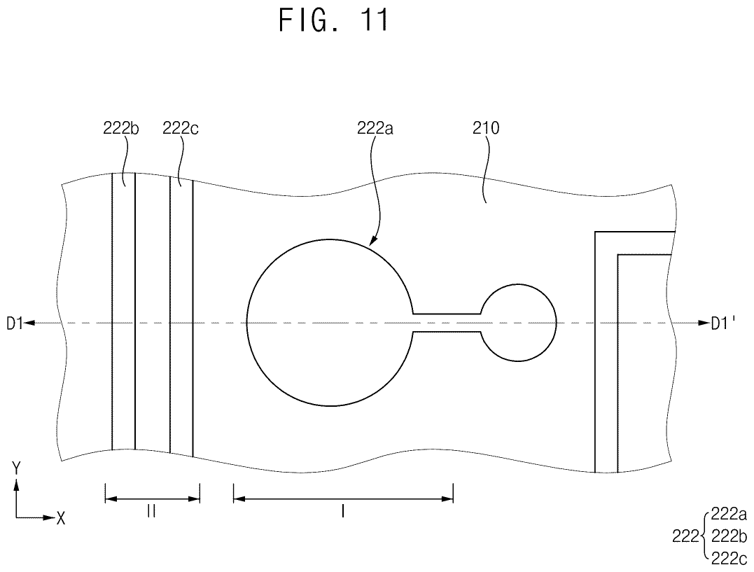

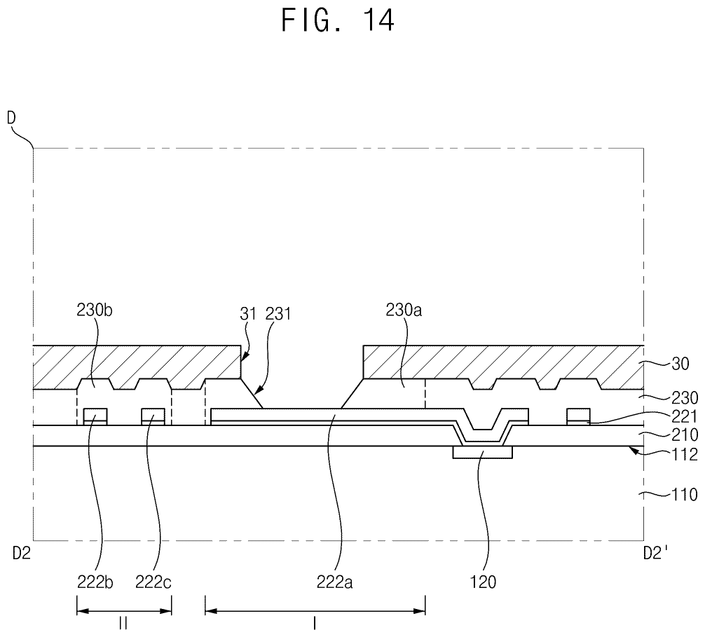

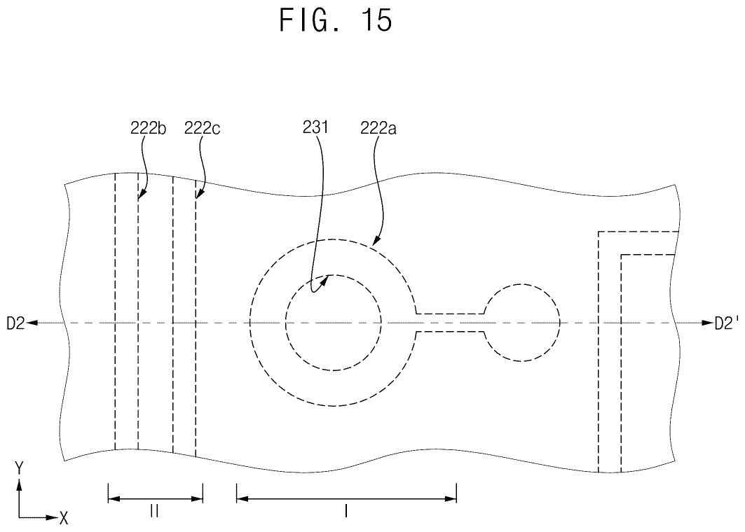

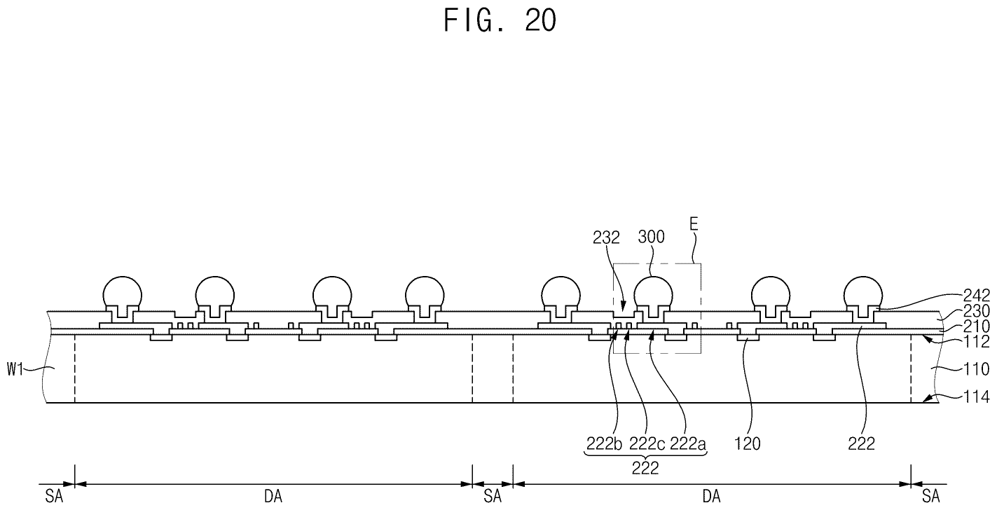

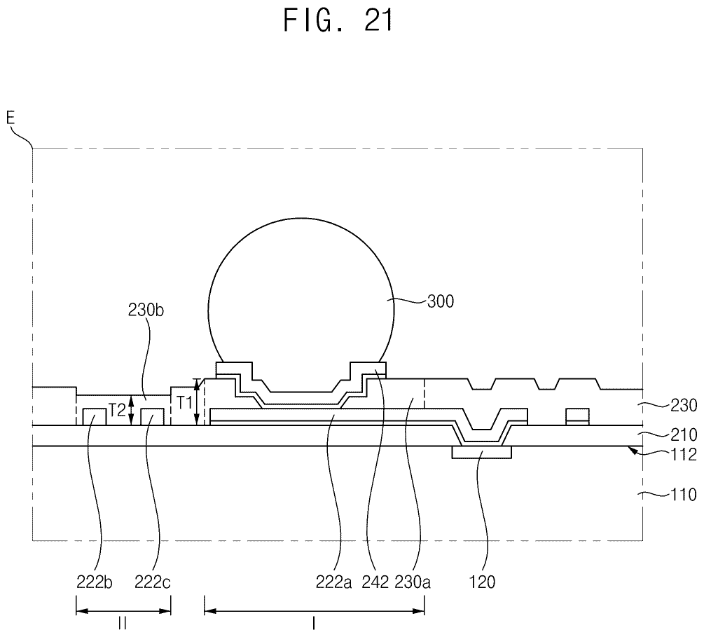

FIGS. 5 to 21 are views illustrating a method of manufacturing a semiconductor package in accordance with example embodiments. FIG. 5 is a plan view illustrating a wafer in which semiconductor chips are formed. FIGS. 6, 7 and 20 are cross-sectional views taken along the line C-C′ in FIG. 5. FIGS. 8 to 10, 12 to 14 and 16 to 19 are enlarged cross-sectional views illustrating portion ‘D’ in FIG. 7. FIG. 11 is a plan view illustrating redistribution wirings in FIG. 10. FIG. 15 is a plan view illustrating a protective layer in FIG. 14. FIG. 21 is an enlarged cross-sectional view illustrating portion ‘E’ in FIG. 20. FIG. 10 is a cross-sectional view taken along the line D1-D1′ in FIG. 11. FIG. 14 is a cross-sectional view taken along the line D2-D2′ in FIG. 15.

Referring to FIGS. 5 and 6, first, a semiconductor wafer W1 in which a plurality of semiconductor chips are formed may be provided.

In example embodiments, the wafer W1 may include a substrate 110 having a first surface 112 and a second surface 114 opposite to the first surface 112. The substrate 110 may include a die region DA and a scribe lane region SA surrounding the die region DA. The substrate 110 may be cut along the scribe lane region SA that divides a plurality of the die regions DA of the wafer W1 by following a sawing process to be individualized into a plurality of semiconductor chips.

Circuit elements may be formed in the die region DA on the first surface 112 of the substrate 110. For example, the circuit elements may include an integrated circuit for performing power source-related functions such as a power management semiconductor, battery management, a DC-DC converter, etc.

For example, the substrate 110 may include a semiconductor material such as silicon, germanium, silicon-germanium, or a group III-V compound semiconductor such as gallium phosphide (GaP), gallium arsenide (GaAs), or gallium antimonide (GaSb). In some embodiments, the substrate 110 may be a silicon-on-insulator (SOI) substrate or a germanium-on-insulator (GOI) substrate.

The circuit elements may include, for example, transistors, capacitors, wiring structures, etc. The circuit elements may be formed by performing a fabrication (e. g,. fab) process called a front end of line (FEOL) process for manufacturing semiconductor devices on the first surface 112 of the substrate 110. A surface of the substrate on which the FEOL process is performed may be referred to as a front side surface of the substrate, and a surface opposite to the front side may be referred to as a backside surface. An insulation interlayer may be formed on the first surface 112 of the substrate 110 to cover the circuit elements.

In example embodiments, a plurality of chip pads 120 may be formed on the first surface 112 of the substrate 110. The chip pads 120 may be electrically connected to the circuit elements through contact plugs in the insulation interlayer. A passivation layer may be formed on the insulation interlayer on the first surface 112 of the substrate 110. At least portions of the chip pads 120 may be exposed by the passivation layer.

Referring to FIGS. 7 to 19, a redistribution wiring layer 200 may be formed on the first surface 112 of the substrate 110. The redistribution wiring layer 200 may include at least one insulating layer 210, redistribution wirings 222 provided in the at least one insulating layer 210 and electrically connected to the chip pads 120, and a protective layer 230 as a passivation layer on the at least one insulating layer 210 and covering the redistribution wirings 222.

As illustrated in FIGS. 7 and 8, a first insulating layer 210 having openings 211 that expose the chip pads 120 may be formed on the first surface 112 of the substrate 110. The first insulating layer may include a polymer or a dielectric layer. For example, the first insulating layer may include a photosensitive dielectric layer such as PID (photo imageable dielectric). The first insulating layer may be formed by a vapor deposition process, a spin coating process, etc.

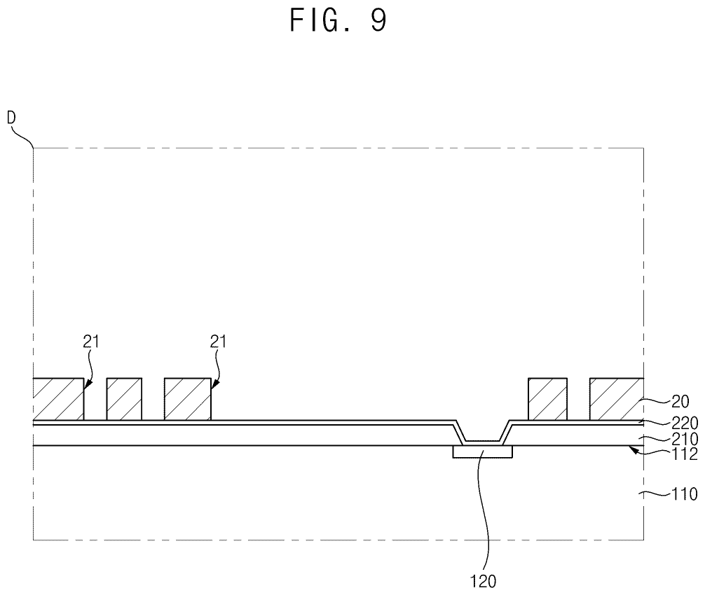

As illustrated in FIGS. 9 to 11, the redistribution wirings 222 may be formed on the first insulating layer 210 to be electrically connected to the chip pads 120 through the openings 211.

In particular, as illustrated in FIG. 9, a first seed layer 220 may be formed on the first insulating layer 210 and the chip pads 120 in the opening 211, and a first photoresist pattern 20 having openings 21 that expose redistribution wiring regions may be formed on the first seed layer 220.

As illustrated in FIGS. 10 and 11, an electrolytic plating process may be performed to form the redistribution wirings 222 in the openings 21 of the first photoresist pattern 20. Then, the first photoresist pattern 20 may be removed by a strip process, and portions of the first seed layer 220 exposed by the redistribution wirings 222 may be etched to form a first seed layer pattern 221. The redistribution wirings may include aluminum (Al), copper (Cu), tin (Sn), nickel (Ni), gold (Au), platinum (Pt), or an alloy thereof. Alternatively, the redistribution wirings may be formed by an electroless plating process, a vapor deposition process, etc.

The redistribution wirings 222 may include a first redistribution wiring 222a on which an under bump metallurgy (UBM) pad is disposed, and second and third redistribution wirings 222b, 222c adjacent to each other. A spacing distance S between the second and third redistribution wirings 222b, 222c may be within a range of 3 μm to 30 μm. The redistribution wiring layer 200 may include a first region I on which the UBM pad is disposed, and a second region II on which the second and third redistribution wirings 222b, 222c adjacent to each other are disposed.

In the second region II, two adjacent second and third redistribution wirings 222b, 222d may be disposed, but the present disclosure may not be limited thereto, and, for example, three or more redistribution wirings adjacent to each other may extend in the second region II. In addition, the adjacent redistribution wirings within the second region II may extend in one direction (Y direction), for example they may be parallel.

The first redistribution wiring 222a may be electrically connected to the chip pad 120 through the opening 211 of the first insulating layer 210. The first redistribution wiring 222a may include a redistribution via disposed within the opening 211 of the first insulating layer 210, a redistribution line extending from the redistribution via on the first insulating layer 210, and a redistribution pad in one end portion of the redistribution line. The UBM pad may be disposed on the redistribution pad, which is a portion of the first redistribution wiring 222a.

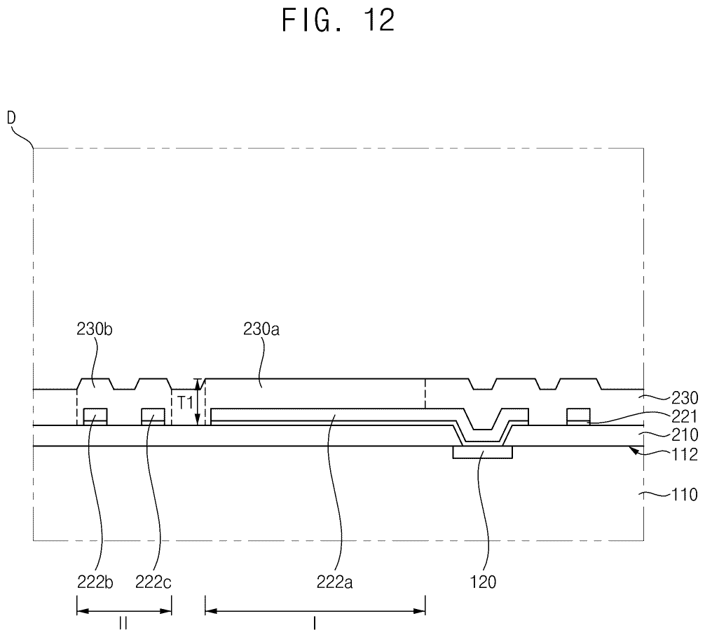

Then, as illustrated in FIG. 12, a protective layer 230 may be formed on the first insulating layer 210 to cover the redistribution wirings 222. The protective layer 230 may include a first cover portion 230a provided in the first region I and a second cover portion 230b provided in the second region II. The first cover portion 230a may cover a portion of the first redistribution wiring 222a on which the UBM pad is disposed. The second cover portion 230b may cover the second and third redistribution wirings 222b, 222c that are adjacent to each other.

The protective layer 230 may include a polymer or a dielectric layer. For example, the protective layer may include an oxide layer, a nitride layer, or a combination thereof. The protective layer may include a thermosetting resin such as epoxy mold compound (EMC), or an insulating material such as polyimide. The protective layer may include a photosensitive dielectric layer such as photo imageable dielectric (PID) or a non-photosensitive dielectric layer. The protective layer may be formed by a vapor deposition process, a spin coating process, a molding process, a lamination process, a coating process, etc.

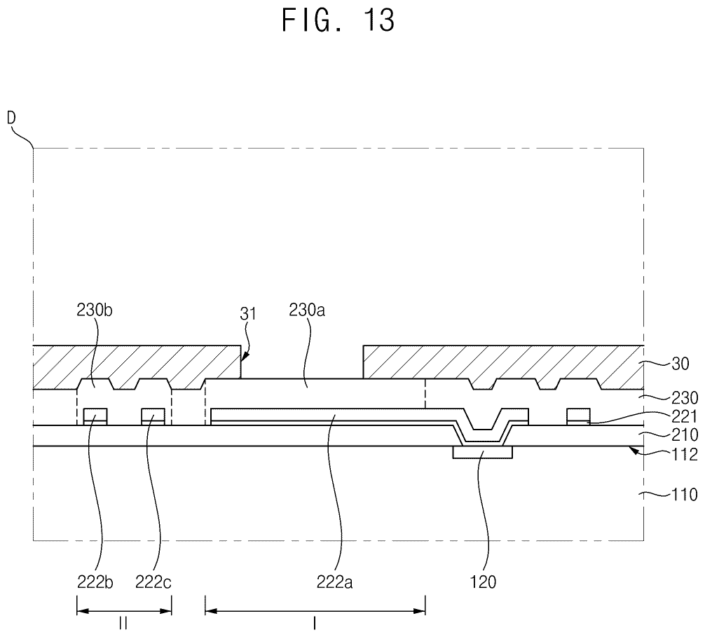

As illustrated in FIGS. 13 to 15, a second photoresist pattern 30 having an opening 31 that exposes a region corresponding to a portion of a first redistribution wiring 222a may be formed on the protective layer 230, and a first etching process may be performed using the second photoresist pattern 30 as an etching mask to form a first opening 231 in the first cover portion 230a. Then, the second photoresist pattern 30 may be removed. A sidewall of the first opening 231 may be inclined by a predetermined angle with respect to an upper surface of the protective layer. A diameter of the first opening 231 may be determined in consideration of a diameter of the UBM pad.

When the protective layer 230 includes a photosensitive dielectric layer, a first photolithography process using a mask such as a phase shift mask may be performed on the protective layer 230 to form the first opening 231 (e.g., see FIG. 14) in the first cover portion 230a.

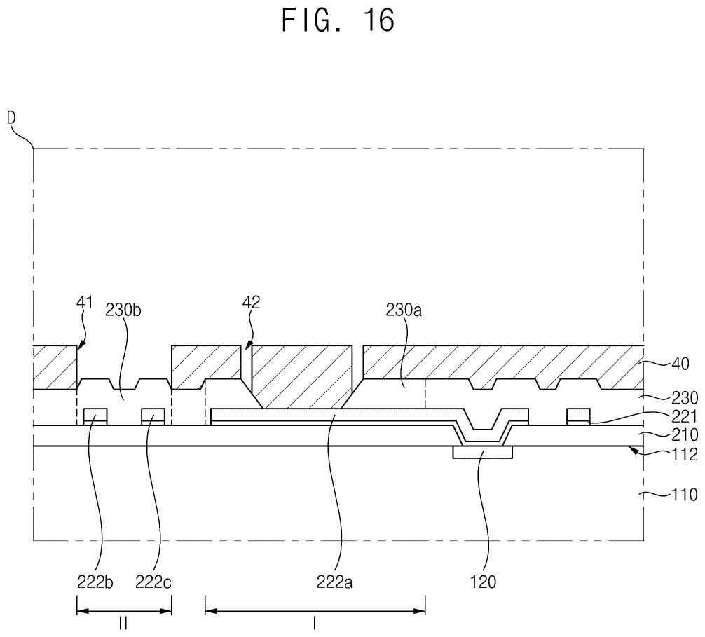

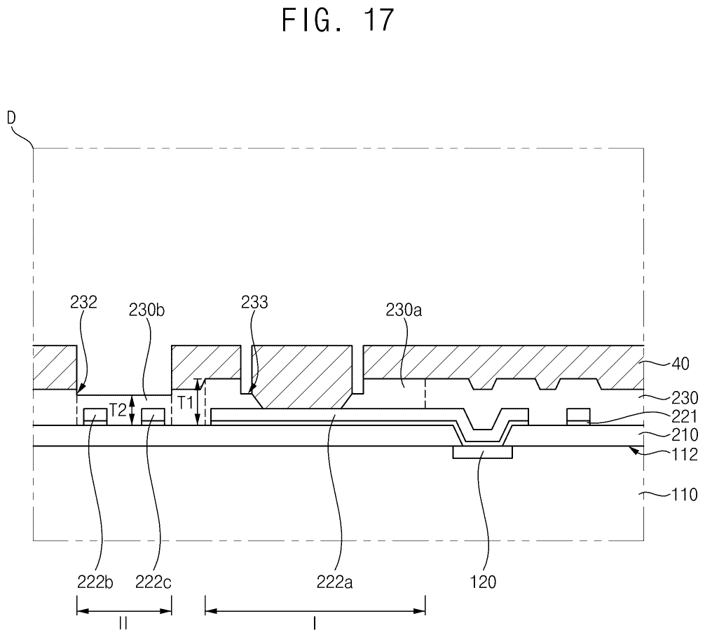

As illustrated in FIGS. 16 and 17, a third photoresist pattern 40 having an opening 41 that exposes a second cover portion region and an opening 42 that exposes a region corresponding to a portion of the sidewall of the first opening 231 may be formed on the protective layer 230, and a second etching process may be performed using the third photoresist pattern 40 as an etching mask to form a second opening 232 in the second cover portion 230b and form a step portion 233 in the sidewall of the first opening 231 together. The step portion 233 may have an annular shape when viewed in a plan view. A width of the annular shape of the step portion 233 may be within a range of 2.5% to 5% of the diameter of the first opening 231.

When the protective layer 230 includes a photosensitive dielectric layer, a second photolithography process using a mask such as a phase shift mask may be performed on the protective layer 230 to form the second opening 232 in the second cover portion 230b and simultaneously form the step portion 233 in the sidewall of the first opening 231.

Accordingly, the protective layer 230 may include the first cover portion 230a having the first opening 231 that exposes the portion of the first redistribution wiring 222a and the second cover portion 230b covering the second and third redistribution wirings 222b, 222c adjacent to each other. The second opening 232 may have a predetermined depth d (not labeled) from the upper surface of the protective layer 230. The first cover portion 230a may have a first thickness T1, and the second cover portion 230b may have a second thickness T2 less than the first thickness T1. In some examples, the first cover portion 230a and second cover portion 230b may be part of the protective layer 230. For example, they may contain the same material or materials as the protective layer 230.

The first thickness T1 of the first cover portion 230a of the protective layer 230 may be within a range of 10 μm to 20 μm, and the second thickness T2 of the second cover portion 230b of the protective layer 230 may be within a range of 8 μm to 14 μm. A thickness T3 of the redistribution wiring 222 may be within a range of 6 μm to 12 μm.

A thickness of the remaining portion of the protective layer 230 excluding the second cover portion 230b may be greater than the second thickness T2 of the second cover portion 230b. Since the remaining portion of the protective layer 230 includes the first cover portion 230a and has a relatively large thickness, the redistribution wiring 222 may be formed to have the relatively large thickness T3, to thereby improve power transmission characteristics.

In addition, since the second cover portion 230b of the protective layer 230 has a relatively thin thickness T2, in a visual inspection process after a packaging process, refraction of light reflected from the adjacent second and third redistribution wirings 222b, 222c and a difference in shading above the second and third redistribution wirings may be reduced, thereby improving detection reliability.

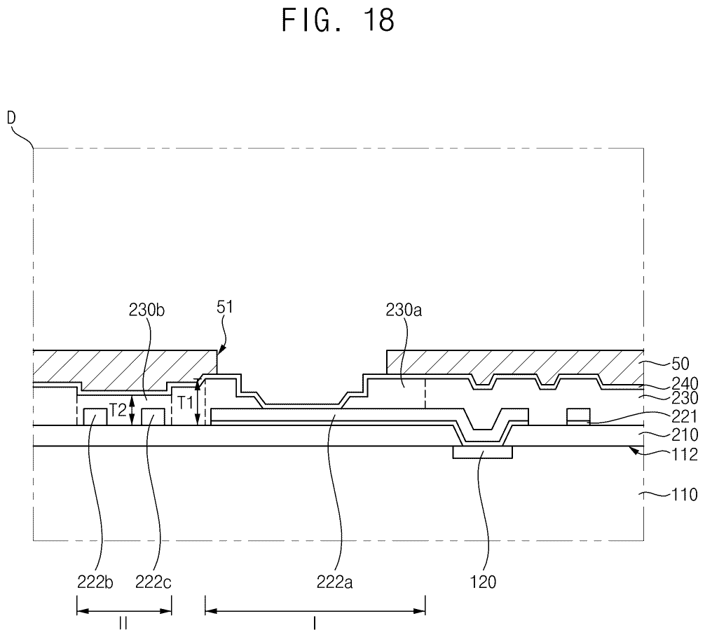

Then, as illustrated in FIG. 18, a second seed layer 240 may be formed on the protective layer 230, and a fourth photoresist pattern 50 having an opening 51 that exposes an UBM pad region may be formed on the second seed layer 240.

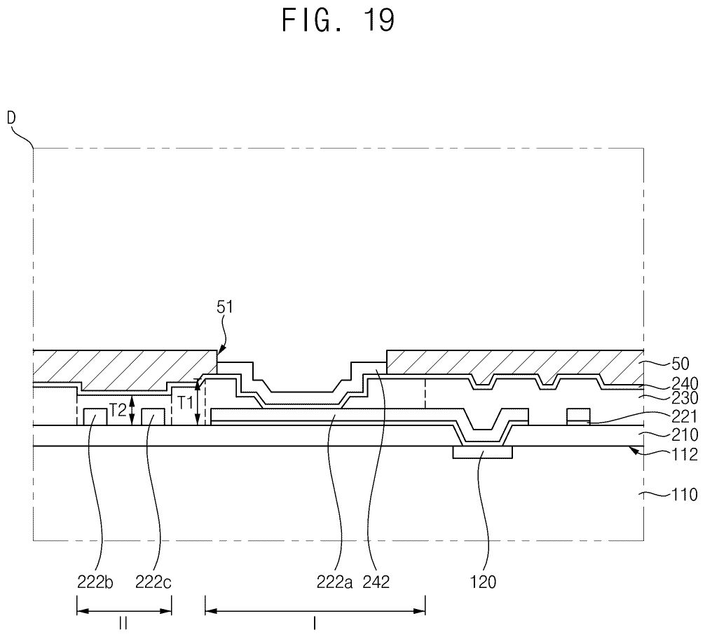

Then, as illustrated in FIG. 19, an electrolytic plating process may be performed to form an UBM pad 242 as a bonding pad within the opening 51 of the fourth photoresist pattern 50. In addition, the fourth photoresist pattern 50 may be removed by a strip process, and a portion of the second seed layer 240 exposed by the UBM pad 242 may be etched to form a second seed layer pattern 243 (not shown).

Accordingly, the UBM pad 242 may be formed on a portion of the first redistribution wiring 222a. The UBM pad 242 may include a single plating pattern layer such as copper. Alternatively, the UBM pad 242 may include both the plating pattern layer and an additional plating pattern layer formed on the plating pattern layer. The additional plating pattern layer may include a metal such as nickel or gold. For example, a diameter of the UBM pad 242 may be within a range of 100 μm to 242 μm.

As the thickness of the remaining portion of the protective layer 230 including the first cover portion 230a increases, the depth of the first opening 231 may deepens, and accordingly, a thickness of a via portion of the UBM pad 242 to be formed within the first opening 231 may increase, which may cause a crack to occur in the UBM pad due to a coefficient of thermal expansion (CTE) mismatch between the protective layer and the UBM pad. In example embodiments, the step portion 233 formed within the first opening 231 may increase a bonding area between the UBM pad 242, so as to provide excellent interfacial adhesion between the UBM pad 242 and the sidewall of the first opening 231 of the protective layer 230. Accordingly, reliability of the disclosed semiconductor package 10 (e.g., in a board level test) may be improved.

In this embodiment, the redistribution wiring layer may be formed to include the first insulating layer 210 and the protective layer (second insulating layer) 230 formed in two layers, and the redistribution wirings provided in the first and second insulating layers. However, the present disclosure may not be limited thereto, and for example, the redistribution wiring layer may include first and second insulating layers and a protective layer (third insulating layer) stacked in at least three layers, and first and second redistribution wirings respectively provided in the first, second, and third insulating layers. In this case, the second redistribution wiring may correspond to an uppermost redistribution wiring among the redistribution wirings, and the UBM pad may be formed on a portion of the uppermost redistribution wiring (second redistribution wiring) exposed by the protective layer.

Referring to FIGS. 20 and 21, conductive bumps 300 as external connection members may be formed on the redistribution wiring layer 200 to be electrically connected to the redistribution wirings 222.

For example, the conductive bumps 300 may be respectively formed on the UBM pads 242 by a ball attach process. The conductive bumps 300 may be formed by applying flux to solder bumps or solder balls and performing a reflow process.

Then, the wafer W1 may be cut along the scribe lane region SA that divides a plurality of the die regions DA of the wafer W1 to complete the semiconductor package of FIG. 1 including an individualized semiconductor chip on the redistribution wiring layer 200.

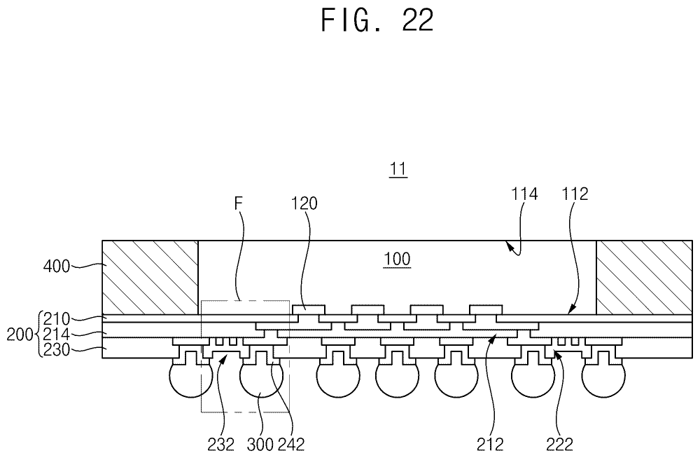

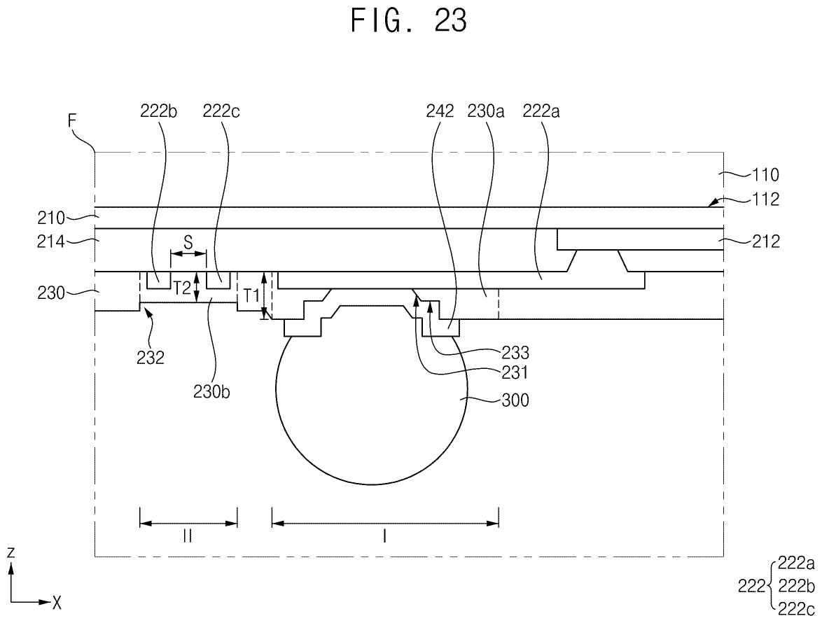

FIG. 22 is a cross-sectional view illustrating a semiconductor package in accordance with example embodiments. FIG. 23 is an enlarged cross-sectional view illustrating portion ‘F’ in FIG. 22. The semiconductor package may be substantially the same as the semiconductor package described with reference to FIGS. 1 to 4 except for a configuration of a redistribution wiring layer and an additional molding member (e.g., an additional mold layer). Thus, same reference numerals will be used to refer to the same or like elements and any further repetitive explanation concerning the above elements will be omitted.

Referring to FIGS. 22 and 23, a semiconductor package 11 may include a redistribution wiring layer 200, a semiconductor chip 100 disposed on a first surface 202 of the redistribution wiring layer 200, a molding member (e.g., mold layer) 400 covering at least one side of the semiconductor chip 100 on the first surface 202 of the redistribution wiring layer 200, and external connection members (e.g., conductive bumps) 300 disposed on a second surface 204 of the redistribution wiring layer 200. For example, the molding member (e.g., mold layer) 400 may be an insulating material, and/or may include organic molding members such as Epoxy Molding Compound (EMC) and/or inorganic molding members such as silicon oxide, silicon nitride, silicon oxynitride, an insulating material with a lower dielectric constant than silicon oxide, or a combination thereof.

The semiconductor package 11 may be a fan-out wafer level package (FOWLP).

In example embodiments, the semiconductor chip 100 may have a plurality of chip pads 120 on a first surface 112, e.g., an active surface thereof. The semiconductor chip 100 may be provided in the molding member 400 such that the first surface 112 on which the chip pads 120 are formed faces the redistribution wiring layer 200. A second surface 114 of the semiconductor chip 100 opposite to the first surface 112 may be exposed by the molding member 400.

In example embodiments, the redistribution wiring layer 200 may include at least one insulating layer (e.g., first insulating layer 210, second insulating layer 214, and/or protective layer 230), redistribution wirings 212, 222 (which may also be lowermost redistribution wirings 212 and uppermost redistribution wirings 222, respectively) formed on the at least one insulating layer and electrically connected to the chip pads 120, and under bump metallurgy (UBM) pads 242 respectively disposed on portions of uppermost redistribution wirings 222 among the redistribution wirings 212, 222.

In particular, the redistribution wiring layer 200 may include a first insulating layer 210 formed on a lower surface of the molding member 400 and having openings that expose the chip pads 120, and lowermost redistribution wirings 212 formed on the first insulating layer 210 and electrically connected to the chip pads 120 through the openings.

The redistribution wiring layer 200 may include a second insulating layer 214 formed on the first insulating layer 210 and having openings that expose the lowermost redistribution wirings 212, and uppermost redistribution wirings 222 formed on the second insulating layer 214 and electrically connected to the lowermost redistribution wirings 212 through the openings.

The redistribution wiring layer 200 may include a protective layer 230 formed on the second insulating layer 214 and having first openings 231 that expose portions of the uppermost redistribution wirings 222, and the UBM pads 242 formed on the protective layer 230 and electrically connected to the uppermost redistribution wirings 222 through the first openings 231.

The first and second insulating layers and the protective layer may include a polymer, a dielectric layer, or the like. For example, the first and second insulating layers and the protective layer may include a photosensitive insulating film such as a photo imageable dielectric (PID). The lowermost redistribution wiring and the uppermost redistribution wiring may include aluminum (Al), copper (Cu), tin (Sn), nickel (Ni), gold (Au), platinum (Pt), or an alloy thereof.

The lowermost redistribution wirings 212 and the uppermost redistribution wirings 222 may be provided in the first and second insulating layers 210, 214 and the protective layer 230, respectively. The number, arrangement, etc. of the insulating layers and the redistribution wirings of the redistribution wiring layer are provided as examples, and it will be understood that the present inventive concept is not limited thereto.

As illustrated in FIG. 23, the uppermost redistribution wirings 222 may include a first redistribution wiring 222a on which the UBM pad 242 is disposed, and second and third redistribution wirings 222b, 222c adjacent to each other. A spacing distance S between the second and third redistribution wirings 222b, 222c may be within a range of 3 μm to 30 μm. The redistribution wiring layer 200 may include a first region I on which the UBM pad 242 is disposed, and a second region II on which the second and third redistribution wirings 222b, 222c adjacent to each other are disposed. The protective layer 230 may include a first cover portion 230a provided in the first region I and a second cover portion 230b provided in the second region II. The first cover portion 230a may cover a portion of the first redistribution wiring 222a on which the UBM pad 242 is disposed. The second cover portion 230b may cover the second and third redistribution wirings 222b, 222c that are adjacent to each other.

The first cover portion 230a may have a first opening 231 that exposes a portion of the first redistribution wiring 222a. A sidewall of the first opening 231 may be inclined by a predetermined angle with respect to an upper surface of the first cover portion. The second cover portion 230b may include a second opening 232 having a predetermined depth d (not labeled) from an upper surface of the protective layer 230. Accordingly, the first cover portion 230a may have a first thickness T1, and the second cover portion 230b may have a second thickness T2 less than the first thickness T1.

A step portion 233 may be provided in the sidewall of the first opening 231. The step portion 233 may have an annular shape when viewed in a plan view. A width of the annular shape of the step portion 233 may be within a range of 2.5% to 5% of the diameter of the first opening 231.

The UBM pad 242 may be formed on a portion of the first redistribution wiring 222a. The UBM pad 242 may have a via portion provided within the first opening 231. The UBM pad 242 may include a seed layer pattern and a plating pattern layer. The UBM pad 242 may include a single plating pattern layer such as copper. Alternatively, the UBM pad 242 may include the plating pattern layer and an additional plating pattern layer formed on the plating pattern layer. The additional plating pattern layer may include a metal such as nickel or gold. For example, a diameter of the UBM pad 242 may be within a range of 100 μm to 250 μm.

In example embodiments, conductive bumps 300 as the external connection members (e.g., external connection terminals) may be respectively disposed on the UBM pads 242. A respective conductive bump 300 may be provided on the portion of the first redistribution wiring 222a exposed by the UBM pad 242.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a semiconductor chip having chip pads on a first surface thereof, wherein the first surface is a horizontal surface;
a redistribution wiring layer covering the first surface of the semiconductor chip, the redistribution wiring layer including redistribution wirings provided on at least one insulating layer and electrically connected to the chip pads, a protective layer on the at least one insulating layer, wherein the protective layer covers the redistribution wirings and includes a first cover portion having a first opening that exposes a portion of a first redistribution wiring of the redistribution wirings with respect to the first cover portion and a second cover portion covering second and third redistribution wirings adjacent to each other of the redistribution wirings, and an under bump metallurgy (UBM) pad provided on the portion of the first redistribution wiring exposed by the first opening, and wherein the protective layer including the first and second cover portions is a continuous integral structure; and
conductive bumps disposed on the UBM pads of the redistribution wiring layer,
wherein the first cover portion has a first thickness in a vertical direction, and the second cover portion has a second thickness in the vertical direction less than the first thickness.

2. The semiconductor package of claim 1, wherein the second cover portion has a second opening having a predetermined depth from an upper surface of the protective layer.

3. The semiconductor package of claim 1, wherein a step portion is provided in a sidewall of the first opening.

4. The semiconductor package of claim 3, wherein the UBM pad covers the step portion in the sidewall of the first opening.

5. The semiconductor package of claim 1, wherein the first thickness is within a range of 10 μm to 20 μm, and the second thickness is within a range of 8 μm to 14 μm.

6. The semiconductor package of claim 5, wherein a thickness of a respective redistribution wiring is within a range of 6 μm to 12 μm.

7. The semiconductor package of claim 1, wherein a spacing distance between the second and third redistribution wirings is within a range of 3 μm to 30 μm.

8. The semiconductor package of claim 1, wherein the protective layer includes a photosensitive dielectric layer.

9. The semiconductor package of claim 1, wherein the UBM pad and the redistribution wirings include copper, and the conductive bumps include solder.

10. The semiconductor package of claim 1, further comprising
a mold layer covering side surfaces of the semiconductor chip, and
wherein the redistribution wiring layer is disposed on a lower surface of the mold layer to cover the first surface of the semiconductor chip.

11. The semiconductor package of claim 1, wherein the first thickness is the maximum vertical thickness of the first cover portion, and the second thickness is the maximum vertical thickness of the second cover portion.

12. The semiconductor package of claim 1, wherein the first cover portion covers a first region on a first side of the UBM pad, and the second cover portion covers a second region on a second side of the UBM pad opposite the first side.

13. A semiconductor package, comprising:
a semiconductor chip having chip pads on a first surface thereof, wherein the first surface is a horizontal surface;
a redistribution wiring layer covering the first surface of the semiconductor chip and having redistribution wirings electrically connected to the chip pads; and
conductive bumps disposed on an outer surface of the redistribution wiring layer and electrically connected to the redistribution wirings,
wherein the redistribution wiring layer includes:
the redistribution wirings provided on at least one insulating layer;
a protective layer provided on the at least one insulating layer and covering the redistribution wirings, the protective layer including a first cover portion having a first opening that exposes a portion of a first redistribution wiring of the redistribution wirings with respect to the first cover portion, and a second cover portion covering second and third redistribution wirings adjacent to each other of the redistribution wirings, wherein the protective layer including the first and second cover portions is a continuous integral structure; and
a bonding pad provided on the portion of the first redistribution wiring,
wherein the conductive bumps are disposed on the bonding pads respectively, and
wherein the first cover portion has a first thickness in a vertical direction, and the second cover portion has a second thickness in the vertical direction less than the first thickness.

14. The semiconductor package of claim 13, wherein the second cover portion has a second opening with a predetermined depth from an upper surface of the protective layer.

15. The semiconductor package of claim 13, wherein a step portion is provided in a sidewall of the first opening.

16. The semiconductor package of claim 15, wherein the bonding pad covers the step portion in the sidewall of the first opening.

17. The semiconductor package of claim 13, wherein the first thickness is within a range of 10 μm to 20 μm, and the second thickness is within a range of 8 μm to 14 μm.

18. The semiconductor package of claim 13, wherein a spacing distance between the second and third redistribution wirings is within a range of 3 μm to 30 μm.

19. The semiconductor package of claim 13, further comprising
a mold layer covering side surfaces of the semiconductor chip, and
wherein the redistribution wiring layer is disposed on a lower surface of the mold layer to cover the first surface of the semiconductor chip.

20. A semiconductor package, comprising:
a redistribution wiring layer having at least one insulating layer and redistribution wirings provided on the at least one insulating layer;
a semiconductor chip arranged on an upper surface of the redistribution wiring layer and having chip pads that are electrically connected to the redistribution wirings, wherein the upper surface is horizontal; and
external connection terminals disposed on a lower surface of the redistribution wiring layer and electrically connected to the redistribution wirings,
wherein the redistribution wiring layer further includes:
a protective layer provided on the at least one insulating layer and covering the redistribution wirings, the protective layer including a first cover portion having a first opening that exposes a portion of a first redistribution wiring of the redistribution wirings with respect to the first cover portion, and a second cover portion covering second and third redistribution wirings adjacent to each other of the redistribution wirings, wherein a topmost surface of the first cover portion and a topmost surface of the second cover portion are on the same horizontal plane, and a bottom surface of the first cover portion and a bottom surface of the second cover portion are on different horizontal planes such that the bottom surface of the first cover portion is lower than the bottom surface of the second cover portion, and the first cover portion and second cover portion have the same material composition from their respective topmost surfaces to their respective bottom surfaces; and
a bonding pad provided on the portion of the first redistribution wiring,
wherein an external connection terminal of the external connection terminals is disposed on the bonding pad, and
wherein the first cover portion has a first thickness in a vertical direction, and the second cover portion has a second thickness in the vertical direction less than the first thickness.
